(19) United States
(12) Patent Application Publication
(10) Pub. No.: US 2011/0095288 A1
(43) Pub. Date: Apr. 28, 2011

(54) THIN FILM TRANSISTOR AND DISPLAY DEVICE

(75) Inventors: Narihiro Morosawa, Kanagawa (JP); Toshiaki Arai, Kanagawa (JP)

(73) Assignee: SONY CORPORATION, Tokyo (JP)

(21) Appl. No.: 13/000,446

(22) PCT Filed: Jun. 24, 2009
(86) PCT No.: PCT/JP2009/061507

§ 371 Date: Dec. 21, 2010

(30) Foreign Application Priority Data
Jul. 3, 2008 (JP) 2008-174469

(51) Int. Cl. H01L 29/786; H01L 21/44; H01L 33/28

(52) U.S. Cl. 257/43; 438/104; 257/E29.296; 257/E21.476; 257/E33.019

(57) ABSTRACT

There is provided a thin film transistor capable of suppressing generation of a leak current in an oxide semiconductor film. A thin film transistor 1 includes a gate electrode 12 on a substrate 11, and includes a gate insulating film 13 so as to cover the gate electrode 12 and the substrate 11. An oxide semiconductor film 14 is formed in a region corresponding to the gate electrode 12 on the gate insulating film 13, and a source electrode 15A and a drain electrode 15B are provided with a predetermined interval in between on the oxide semiconductor film 14. A protective film 16 is formed over a whole surface of the substrate 11 so as to cover a channel region 14A of the oxide semiconductor film 14, the source electrode 15A, and the drain electrode 15B. The protective film 16 is composed of an aluminum oxide film, and this aluminum oxide film is formed by an atomic layer deposition method. An entry of hydrogen into the oxide semiconductor film 14 is suppressed by the protective film 16.

### TECHNICAL FIELD

The present invention relates to a thin film transistor using an oxide semiconductor film, and a display device using the thin film transistor.

### BACKGROUND ART

In recent years, for the purpose of application to an electronic device such as a thin film transistor (TFT: Thin Film Transistor), a light emitting device, and a transparent conductive film, study and development of a semiconductor thin film layer (hereinafter, referred to as an oxide semiconductor film) using zinc oxide, indium gallium zinc oxide, or the like have been activated. It is known that such an oxide semiconductor film has the high electron mobility, and the excellent electric characteristics, in comparison with the case where amorphous silicon (α-Si) which is typically used for a liquid crystal display or the like is used. Further, there is an advantage that the high mobility may be expected even at a low temperature around a room temperature, or the like, and development has been actively proceeded.

As the thin film transistor using the oxide semiconductor film as described above, a bottom gate type structure, and a top gate type structure have been reported. The bottom gate type is a structure in which a gate electrode and a gate insulating film are formed in this order on a substrate, and the oxide semiconductor film is formed so as to cover the top face of the gate insulating film.

### CITATION LIST

### Non-Patent Document

Non-patent document 1: Cetin Kilic, et al., “n-type doping of oxides by hydrogen”, APPLIED PHYSICSLETTERS, Jul. 1, 2002, Vol. 81, No.1, pp. 73-75

### SUMMARY OF THE INVENTION

By the way, in the above-described oxide semiconductor film, it has been reported that due to an entry of a hydrogen gas or the like, an electrically-shallow impurity level is formed, and reduction of a resistance is caused (refer to Non-patent document 1). Thus, for example, in the case where the zinc oxide is used for the thin film transistor, the operation is a normally-on type operation in which a drain current is allowed to flow even when a gate voltage is not applied, that is, a depression type operation, and there is an issue that a threshold voltage is reduced with an increase of a defect level, and a leak current is increased. In this manner, the entry of the hydrogen gas into the oxide semiconductor film influences the current transfer characteristics of the thin film transistor.

In view of the foregoing issues, it is an object of the present invention to provide a thin film transistor capable of suppressing generation of a leak current in an oxide semiconductor film, and a display device using the same.

A thin film transistor of the present invention includes: a gate electrode; an oxide semiconductor film in which a channel region is formed corresponding to the gate electrode; a pair of electrodes of a source electrode and a drain electrode formed on the oxide semiconductor film; and one or a plurality of protective films provided so as to face the channel region of the oxide semiconductor film, and at least one protective film in the one or the plurality of protective films contains an aluminum oxide.

A method of manufacturing a thin film transistor of the present invention includes steps of: forming a gate electrode on a substrate; forming an oxide semiconductor film including a channel region corresponding to the gate electrode; forming a pair of electrodes of a source electrode and a drain electrode on the oxide semiconductor film; and forming one or a plurality of protective films so as to face the channel region of the oxide semiconductor film, and at least one protective film in the one or the plurality of protective films is formed of a film containing an aluminum oxide.

A display device of the present invention includes: a display element; and the thin film transistor of the present invention.

In the thin film transistor, the method of manufacturing the thin film transistor, and the display device of the present invention, an entry of an element such as hydrogen into the oxide semiconductor film is suppressed by providing the protective film containing the aluminum oxide so as to face the channel region of the oxide semiconductor film in which the channel region is formed.

According to the thin film transistor, the method of manufacturing the thin film transistor, and the display device of the present invention, since the one or the plurality of protective films are provided so as to face the channel region of the oxide semiconductor film in which the channel region is formed, and at least one protective film of these contains the aluminum oxide, the entry of the hydrogen or the like into the oxide semiconductor film is suppressed, and generation of a leak current may be suppressed. Further, thereby, luminance is improved, and a clear display is available in the display device.

### BRIEF DESCRIPTION OF DRAWINGS

FIG. 1 illustrates a cross-sectional structure of a thin film transistor according to a first embodiment of the present invention.

FIG. 2 is a view for explaining a method of manufacturing the thin film transistor illustrated in FIG. 1.

FIG. 3 illustrates a cross-sectional structure of a thin film transistor according to a second embodiment of the present invention.

FIG. 4 is a view for explaining the method of manufacturing the thin film transistor illustrated in FIG. 3.

FIG. 5 illustrates a cross-sectional structure of a thin film transistor according to a third embodiment of the present invention.

FIG. 6 is a view for explaining the method of manufacturing the thin film transistor illustrated in FIG. 5.

FIG. 7 illustrates current-voltage characteristics of the thin film transistor of FIG. 5, (A) illustrates the case where an ozone treatment is performed, and (B) illustrates the case where the ozone treatment is not performed.

FIG. 8 is illustrates the relationship of an off-leak current to a film thickness of a protective film of the thin film transistor of FIG. 5.

FIG. 9 illustrates the current-voltage characteristics of the thin film transistor of FIG. 5, (A) illustrates the current-voltage characteristics before an annealing treatment, and (B) illustrates the current-voltage characteristics after the annealing treatment.

FIG. 10 illustrates current-voltage characteristics of a thin film transistor of a comparative example.

FIG. 11 illustrates a cross-sectional structure of a thin film transistor according to a modification of the third embodiment.

FIG. 12 is a view for explaining the method of manufacturing the thin film transistor illustrated in FIG. 11.

### DESCRIPTION OF EMBODIMENTS

Hereinafter, a description will be given in detail of embodiments of the present invention with reference to the drawings.

### First Embodiment

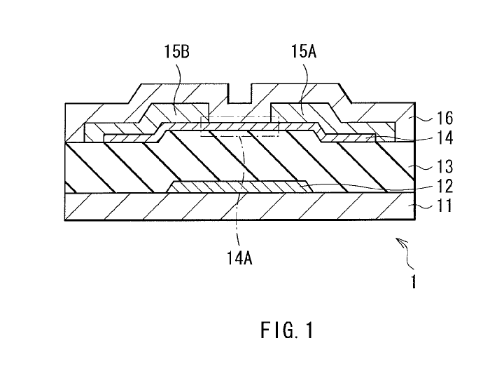

FIG. 1 illustrates the cross-sectional structure of a thin film transistor 1 according to a first embodiment of the present invention. The thin film transistor 1 has, for example, a bottom-gate type structure, and an oxide semiconductor is used for a channel region (active layer). The thin film transistor 1 includes a gate electrode 12 on a substrate 11 which is made of glass, plastic, or the like, and a gate insulating film 13 is provided so as to cover the gate electrode 12 and the substrate 11. An oxide semiconductor film 14 is formed in a region corresponding to the gate electrode 12 on the gate insulating film 13, and a pair of electrodes (a source electrode 15A and a drain electrode 15B) is provided on the oxide semiconductor film 14 with a predetermined interval in between. A protective film 16 is formed over the whole surface of the substrate 11, so as to cover a channel region 14A of the oxide semiconductor film 14, the source electrode 15A, and the drain electrode 15B.

The gate electrode 12 functions to control the electron density in the oxide semiconductor film 14 by a gate voltage applied to the thin film transistor 1. The gate electrode 12 is composed of molybdenum (Mo) or the like.

The gate insulating film 13 is composed of a silicon oxide film, a silicon nitride film, a silicon nitride oxide film, an aluminum oxide film, or the like.

The oxide semiconductor film 14 is composed of the oxide semiconductor, and the channel region 14A is formed between the source electrode 15A and the drain electrode 15B by a voltage application. Here, the oxide semiconductor is an oxide which is formed of an element such as indium (In), gallium (Ga), zinc (Zn), and tin (Su). The oxide semiconductor film 14 has, for example, a thickness of 20 nm to 100 nm both inclusive.

The source electrode 15A and the drain electrode 15B are, for example, composed of a simple substance of molybdenum or chrome (Cr), or a stacked structure of titanium (Ti)/aluminum (Al)/titanium.

The protective film 16 suppresses an entry of hydrogen or the like into the inside of the thin film transistor 1, especially, into the channel region 14A of the oxide semiconductor film 14. The protective film 16 includes the aluminum oxide film (Al₂O₃), and is composed of a single-layer film, or a stacked film of two or more layers. Examples of a dual-layer film include a stacked film of the aluminum oxide film and the silicon nitride film, or a stacked film of the aluminum oxide film and the silicon oxide film. Examples of a triple-layer film include a stacked film of the aluminum oxide film, the silicon nitride film, and the silicon oxide film. The protective film 16 has, for example, a thickness of 10 nm to 100 nm both inclusive, and preferably has a thickness of 50 nm or less.

The above-described thin film transistor 1 may be manufactured, for example, as will be described next.

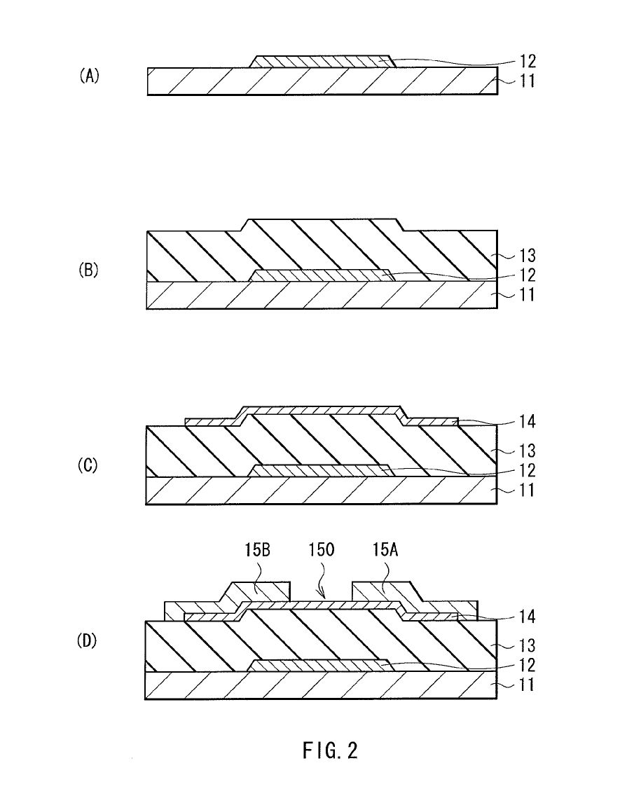

First, as illustrated in FIG. 2(A), after forming a thin metal film over the whole surface of the substrate 11 by sputtering method or evaporation method, this thin metal film is patterned, for example, by etching using a photoresist, and therefore the gate electrode 12 is formed.

Next, as illustrated in FIG. 2(B), the gate insulating film 13 is formed so as to cover the substrate 11 and the gate electrode 12, for example, by plasma CVD (Chemical Vapor Deposition) method.

Next, as illustrated in FIG. 2C, the oxide semiconductor film 14 made of the above-described material, and having the above-described thickness is formed, for example, by sputtering method. For example, in the case where indium gallium zinc oxide (IGZO) is used as the oxide semiconductor, DC sputtering method targeting ceramic of the indium gallium zinc oxide is used, and the oxide semiconductor film 14 is formed by plasma discharge by using a mixed gas of argon (Ar) and oxygen (O₂). However, before performing the plasma discharge, a vacuum container is exhausted until the vacuum level inside of the vacuum container becomes, for example, 1×10⁻⁴ Pa or less, and then the mixed gas of the argon and the oxygen may be introduced. Thereafter, the formed oxide semiconductor film 14 is, for example, patterned by etching using the photoresist.

Next, as illustrated in FIG. 2(D), after the thin metal film is formed on the oxide semiconductor film 14, for example, by sputtering method, an aperture 150 is formed in the region corresponding to the channel region 14A of the oxide semiconductor film 14 in this thin metal film, for example, by etching using the photoresist. Therefore, the source electrode 15A and the drain electrode 15B are formed, respectively.

Next, the protective film 16 made of the above-described material or the like is formed so as to cover the formed oxide semiconductor film 14, the formed source electrode 15A, and the formed drain electrode 15B. In addition, here, the case where a single layer of the aluminum oxide film is formed as the protective film 16 will be described. This protective film 16 is formed, for example, by atomic layer deposition (ALD: Atomic Layer Deposition) method as will be described below. In other words, the substrate 11 above which the oxide semiconductor film 14, the source electrode 15A, and the drain electrode 15B are formed is arranged in a vacuum chamber, a trimethyl aluminum gas as a material gas is introduced, and an aluminum film of an atomic layer is formed on the electrode formation side. Next, an oxygen radical in which an ozone gas or an oxygen gas is excited by plasma is introduced to the side where the aluminum film of the substrate 11 is formed, and therefore the aluminum film is oxidized. Here, since the above-described aluminum film has a film thickness of the level of the atomic layer, the above-described aluminum film is easily oxidized by the ozone or the oxygen radical. Therefore, the aluminum oxide film is formed over the whole surface of the substrate 11. In this manner, by alternately repeating the atomic layer formation process and the oxidation process of the aluminum film, it may be possible to form the aluminum oxide film having the predetermined film thickness.

In this manner, by forming the aluminum oxide film as the protective film 16 by atomic layer deposition method, since lack of the oxygen does not occur in the oxidation process, an ideal composition as the stoichiometric ratio is easily realized. For example, the composition ratio of the aluminum and the oxygen may be ideally 2:3. Further, since the film may be formed in the state where generation of the hydrogen gas is suppressed, the electric characteristics of the oxide semiconductor film 14 are not deteriorated. Therefore, it may be possible to form the protective film 16 having the excellent gas barrier characteristics. As described above, the thin film transistor 1 illustrated in FIG. 1 is completed.

Next, actions and effects of the thin film transistor 1 of this embodiment will be described.

In the thin film transistor 1, when a gate voltage Vg of a predetermined threshold voltage or more is applied between the gate electrode 12 and the source electrode 15A through a wiring layer which is not illustrated in the figure, the channel region 14A is formed in the oxide semiconductor film 14, a current (a drain current Id) is allowed to flow between the source electrode 15A and the drain electrode 15B, and this functions as a transistor.

In the case where an element such as the hydrogen enters inside of the thin film transistor 1, as described above, the electrically-shallow impurity level is formed in the oxide semiconductor film 14, and reduction of the resistance is generated. Thus, for example, in the case where the zinc oxide is used as the oxide semiconductor film 14, the drain current Id is allowed to flow even when the gate voltage Vg is not applied, and the leak current is increased.

On the other hand, in this embodiment, the protective film 16 made of the aluminum oxide film is provided so as to cover the channel region 14A, the source electrode 15A, and the drain electrode 15B, and therefore the entry of the hydrogen into the oxide semiconductor film 14 is suppressed by the gas barrier characteristics of the aluminum oxide film. Therefore, generation of the leak current as described above may be suppressed. Further, by forming this aluminum oxide film by atomic layer deposition method as described above, the more excellent gas barrier characteristics may be realized. Therefore, it may be possible to effectively suppress generation of the leak current.

For example, the thin film transistor 1 as described above may be suitably used as a drive element in a display device such as an organic EL display and a liquid crystal display. In such a display device, since the leak current may be suppressed by including the above-described thin film transistor 1, it may be possible to realize a clear display with high luminance. Further, since the protective film 16 of the aluminum oxide film prevents the entry of the hydrogen or the like from the outside, the reliability is improved.

### Second Embodiment

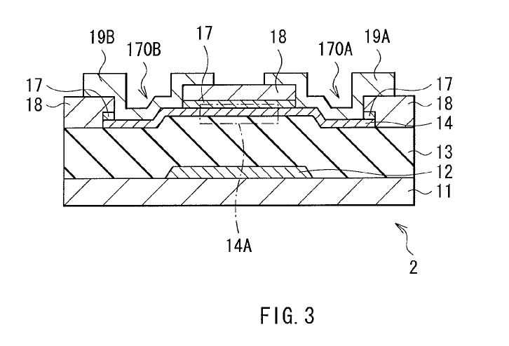

FIG. 3 illustrates the cross-sectional structure of a thin film transistor 2 according to a second embodiment of the present invention. Like the above-described first embodiment, the thin film transistor 2 has the bottom-gate type structure, and the oxide semiconductor is used for the channel region (active layer). Hereinafter, same reference numerals will be used for components identical to those of the above-described first embodiment, and the description will be appropriately omitted.

In the thin film transistor 2, the gate electrode 12, the gate insulating film 13, and the oxide semiconductor film 14 are provided on the substrate 11. In this embodiment, a channel protective film 17 (first protective film) is formed on the top face of the oxide semiconductor film 14, and a protective film 18 (second protective film) is formed so as to cover the top face of this channel protective film 17 and the side face of the oxide semiconductor film 14. Apertures 170A and 170B are provided in the channel protective film 17 and the protective film 18, and a source electrode 19A and a drain electrode 19B are embedded in these apertures 170A and 170B, respectively.

The channel protective film 17 is formed so as to cover the top face of the oxide semiconductor film 14. This channel protective film 17 functions to prevent mechanical damage of the oxide semiconductor film 14, and to suppress desorption of the oxygen or the like in the oxide semiconductor film 14, for example, due to heat treatment in the manufacturing process. Further, the channel protective film 17 functions to protect the oxide semiconductor film 14 from a resist stripping liquid in the manufacturing process. Such a channel protective film 17 is composed of the same material as the protective film 16 of the above-described first embodiment.

The protective film 18 is provided for the purpose of protecting inside of the thin film transistor 2, and composed of the same material as the protective film 16 of the above-described first embodiment.

The above-described thin film transistor 2 may be manufactured, for example, as will be described next.

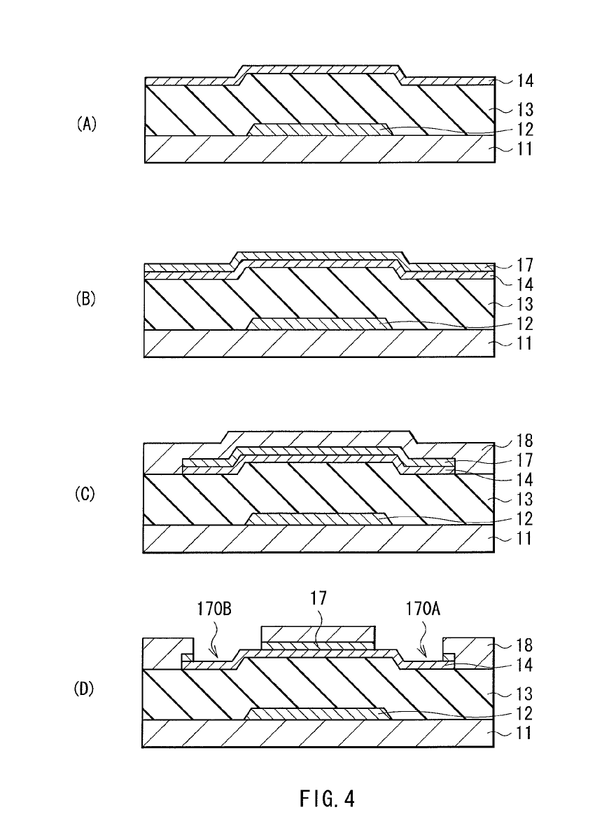

First, as illustrated in FIG. 4(A), the oxide semiconductor film 14 is formed over the whole surface of the gate insulating film 13 by the above-described method.

Next, as illustrated in FIG. 4(B), the channel protective film 17 is formed over the whole surface of the formed oxide semiconductor film 14, for example, by atomic layer deposition method as described above.

Next, as illustrated in FIG. 4(C), the channel protective film 17 and the oxide semiconductor film 14 which have been formed over the whole surface are patterned by etching using the photoresist. Thereafter, the protective film 18 is formed so as to cover the top face of the patterned channel protective film and the side face of the patterned oxide semiconductor film 14 by atomic layer deposition method as described above.

Next, as illustrated in FIG. 4(D), the apertures 170A and 170B penetrating to the surface of the oxide semiconductor film 14 are formed in the formed channel protective film 17 and the formed protective film 18, for example, by etching using the photoresist.

Finally, the thin metal film is formed so as to fill these apertures 170A and 170B, for example, by sputtering method. Thereafter, the aperture is formed in the region corresponding to the channel region 14A of the formed thin metal film, for example, by etching using the photoresist. Therefore, the source electrode 19A and the drain electrode 19B are formed, respectively. In this manner, the thin film transistor 2 as illustrated in FIG. 3 is completed.

In the thin film transistor 2 of the above-described second embodiment, by the channel protective film 17 formed so as to cover the top face of the oxide semiconductor film 14, it may be possible to prevent the channel region 14A from being damaged by etching when the oxide semiconductor film 14, the source electrode 19A, and the drain electrode 19B are patterned and formed. Further, by the protective film 18 provided so as to cover the top face of the channel protective film 17 and the side face of the oxide semiconductor film 14, it may be possible to suppress the entry of the hydrogen into the oxide semiconductor film 14. Therefore, generation of the leak current may be effectively suppressed in comparison with the first embodiment.

### Third Embodiment

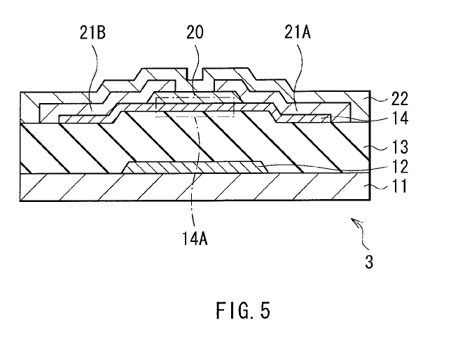

FIG. 5 illustrates the cross-sectional structure of a thin film transistor 3 according to a third embodiment of the present invention. Like the above-described first embodiment, the thin film transistor 3 has the bottom gate type structure, and the oxide semiconductor is used for the channel region (active layer). Hereinafter, same reference numerals will be used for components identical to those of the above-described first embodiment, and the description will be appropriately omitted.

In the thin film transistor 3, the gate electrode 12, the gate insulating film 13, and the oxide semiconductor film 14 are provided on the substrate 11. A channel protective film 20 (first protective film) is formed in the region corresponding to the channel region 14A on the oxide semiconductor film 14. In this embodiment, a source electrode 21A and a drain electrode 21B are provided on the oxide semiconductor film 14 so as to cover end portions of the channel protective film 20. Further, a protective film 22 (second protective film) is formed so as to cover the channel protective film 20, the source electrode 21A, and the drain electrode 21B.

The channel protective film 20 functions to prevent the mechanical damage of the oxide semiconductor film 14, and to suppress the desorption of the element such as the oxygen, for example, in the heat treatment in the manufacturing process. Further, the channel protective film 20 functions to protect the oxide semiconductor film 14 from the resist stripping liquid in the manufacturing process. In this embodiment, this channel protective film 20 is composed of the silicon oxide film.

The protective film 22 is provided for the purpose of protecting inside of the thin film transistor 3, and composed of the same material as the protective film 16 of the above-described first embodiment.

The above-described thin film transistor 3 may be manufactured, for example, as will be described next.

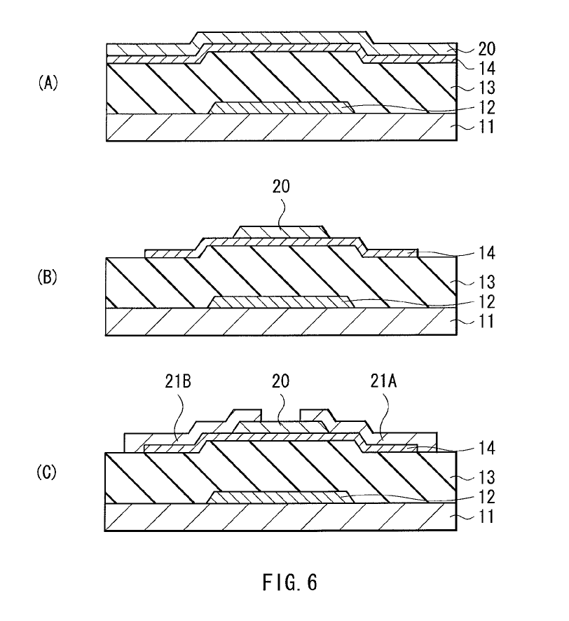

First, as illustrated in FIG. 6(A), after the oxide semiconductor film 14 is formed over the whole surface of the gate insulating film 13 by the above-described method, the channel protective film 20 made of the above-described material is formed, for example, by plasma CVD method. In addition, in this embodiment, it is desirable to perform annealing treatment in an oxygen atmosphere in the subsequent step. Typically, it is known that by placing the oxide semiconductor film in a vacuum atmosphere, the oxygen existed in the film and on the surface is detached. Since the silicon oxide film has oxygen diffusivity, it may be possible to supply the oxygen to the oxide semiconductor film 14 by forming the channel protective film 20 of the silicon oxide film, and performing the annealing treatment on the oxide semiconductor film 14 in the oxygen atmosphere. Therefore, it may be possible to suppress generation of lattice defect in the oxide semiconductor film 14.

Next, as illustrated in FIG. 6(B), the channel protective film 20 and the oxide semiconductor film 14 formed over the whole surface are sequentially patterned by etching using the photoresist.

Next, as illustrated in FIG. 6(C), the thin metal film is formed so as to cover the formed channel protective film 20 and the formed oxide semiconductor film 14, for example, by sputtering method. Thereafter, the aperture is formed in the region corresponding to the channel region 14A of the thin metal film, for example, by etching using the photoresist. Therefore, the source electrode 21A and the drain electrode 21B are formed, respectively.

Meanwhile, as the treatment in the previous step of forming the protective film 22, for example, ozone treatment, oxygen plasma treatment, or nitrogen dioxide plasma treatment is performed on the oxide semiconductor film 14. Such treatment may be performed at any timing after forming the oxide semiconductor film 14, and before forming the protective film 22. However, it is desirable to perform the treatment just before forming the protective film 22. It is possible to suppress generation of the lattice defect in the oxide semiconductor film 14 by performing such a pretreatment.

Finally, the protective film 22 is formed so as to cover the formed channel protective film 20, the formed source electrode 21A, and the formed drain electrode 21B, for example, by atomic layer deposition method described above. As described above, the thin film transistor 3 as illustrated in FIG. 5 is completed.

In the thin film transistor 3 of the above-described third embodiment, by the channel protective film 20 formed on the channel region 14A of the oxide semiconductor film 14, for example, it may be possible to prevent the channel region 14A from being damaged by etching when the source electrode 19A and the drain electrode 19B are formed. Further, by the protective film 22 provided so as to cover the channel protective film 20, the source electrode 21A, and the drain electrode 21B, it may be possible to suppress the entry of the hydrogen into the oxide semiconductor film 14. Therefore, generation of the leak current may be effectively suppressed in comparison with the first embodiment.

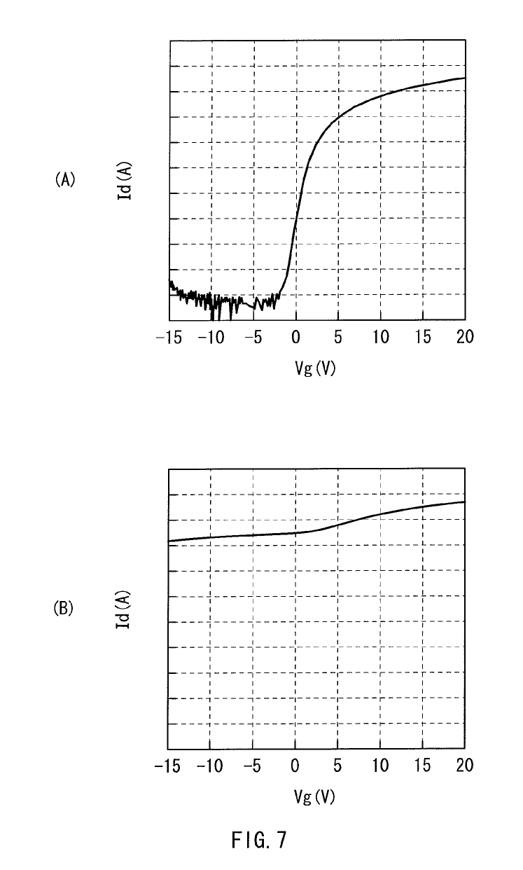

Further, by forming the channel protective film 20 of the silicon oxide film, and performing the annealing treatment on the channel protective film 20 in the oxygen atmosphere, or performing the ozone treatment or the like on the channel protective film 20 before forming the protective film 22, it may be possible to suppress generation of the lattice defect in the oxide semiconductor film 14. Here, current (Id)—voltage (Vg) characteristics of the thin film transistor 3 in the case where the ozone treatment is performed before forming the protective film 22 are illustrated in FIG. 7(A). Further, the current-voltage characteristics in the case where the ozone treatment is not performed are illustrated in FIG. 7(B).

As illustrated in FIG. 7(A), a low off-leak current may be obtained by performing the ozone treatment, and the electric characteristics with a sufficiently-high on-off ratio may be obtained. Meanwhile, as illustrated in FIG. 7(B), in the case where the ozone treatment is not performed, it can be seen that the threshold voltage of the transistor is shifted in the minus direction, and the electric characteristics are highly deteriorated. It is considered that this comes from the following reasons. Typically, in the oxide semiconductor film, the oxygen in the film and on the surface is detached in a vacuum, and therefore the lattice defect is generated. Like the hydrogen gas, such a lattice defect forms the shallow impurity level in the oxide semiconductor film, and the leak current is increased. Further, the lattice defect inhibits induction of a carrier, and the carrier concentration is reduced. This reduction of the carrier concentration reduces the conductivity of the oxide semiconductor film, and influences the electron mobility and the current transfer characteristics (for example, subthreshold characteristics and the threshold voltage) of the thin film transistor. Therefore, by performing the ozone treatment before forming the protective film 22, the sufficient amount of oxygen may be supplied into the oxide semiconductor film 14, generation of the lattice defect is suppressed, and it may be possible to obtain the thin film transistor 3 in which the off-leak current is low, and the on-off ratio is sufficient as a result. In addition, even in the case where the treatment is performed with the radical formed by exciting the oxygen gas and the nitrogen dioxide with the plasma, in substitution for performing the ozone treatment, the same effects as described above may be obtained.

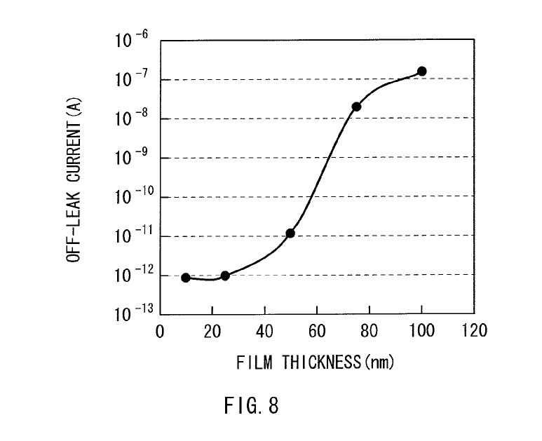

Further, the relationship of the off-leak current of the thin film transistor 3 to the film thickness of the aluminum oxide film as the protective film 22 is illustrated in FIG. 8. However, the above-described ozone treatment is performed before forming the protective film 22. As in the figure, it can be seen that when the film thickness of the protective film 22 is increased to be larger than 50 nm, the off-leak current is increased even when the ozone treatment is performed, and the sufficient on-off ratio may not be obtained. From this, it is desirable to set the film thickness of the aluminum oxide film used as the protective film 22 to be 50 nm or less.

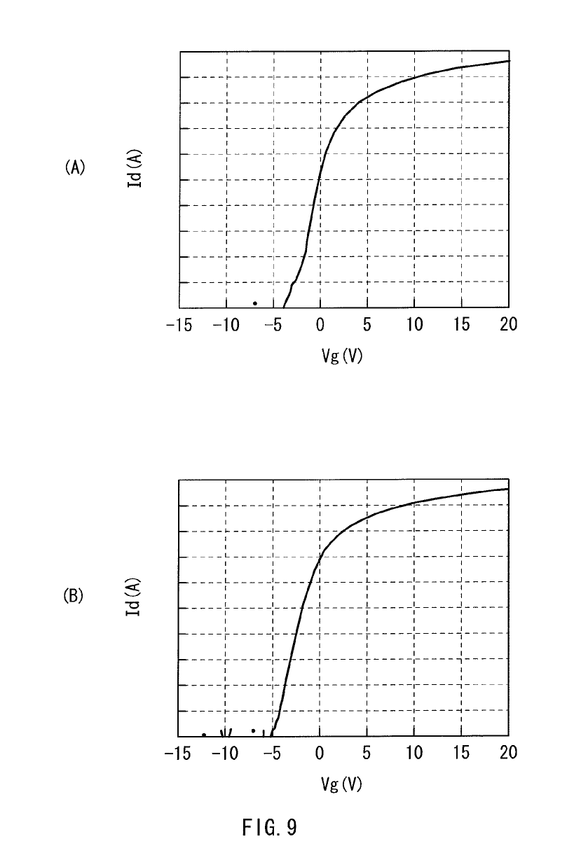

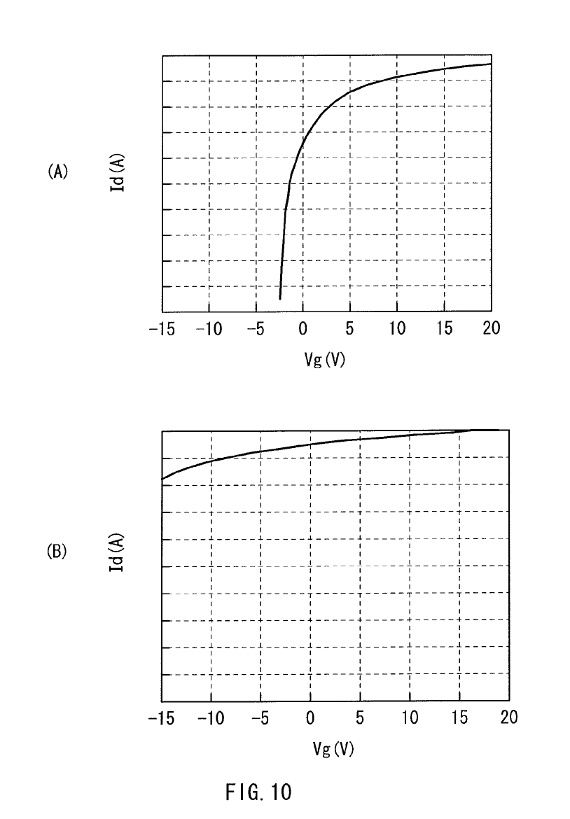

Further, the current-voltage characteristics of the thin film transistor 3 in the case where the protective film 22 of the aluminum oxide film has the film thickness of 10 nm are illustrated in FIGS. 9(A) and 9(B). FIG. 9(A) illustrates initial characteristics, and FIG. 9(B) illustrates the characteristics after annealing is performed for one hour in the nitrogen atmosphere at a temperature of 300° C. Further, as a comparative example of these, the initial characteristics in the case where the protective film 22 is not formed are illustrated in FIG. 10(A), and the characteristics after the annealing is performed for one hour in the nitrogen atmosphere at a temperature of 300° C. are illustrated in FIG. 10(B).

As illustrated in FIGS. 10(A) and 10(B), it can be seen that in the case where the protective film 22 is not formed, the current-voltage characteristics are highly changed after the annealing, and the off-leak current is rapidly increased. On the other hand, as illustrated in FIGS. 9(A) and 9(B), in the thin film transistor 3 of this embodiment in which the aluminum oxide film having the film thickness of 10 nm is formed as the protective film 22, it can seen that the change of the characteristics is hardly seen even after the annealing at 300° C., and the characteristics are stabled. Therefore, it can be seen that even in the heating process which is necessary when the device is manufactured, the stable characteristics may be maintained without deteriorating the transistor characteristics.

### MODIFICATION

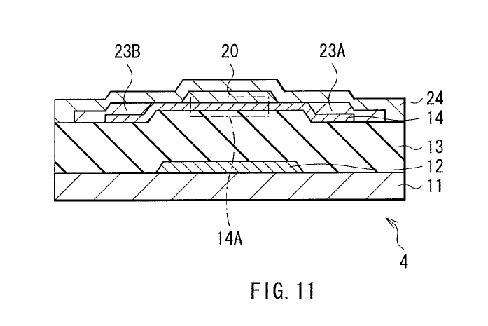

Next, a modification of the above-described third embodiment will be described. FIG. 11 illustrates the cross-sectional structure of a thin film transistor 4 according to the modification. Like the above-described first embodiment, the thin film transistor 4 has the bottom-gate type structure, and the oxide semiconductor is used for the channel region (active layer). Hereinafter, same reference numerals will be used for components identical to those of the above-described first embodiment and the above-described third embodiment, and the description will be appropriately omitted.

In this modification, the structure is the same as the above-described third embodiment except the structure of a source electrode 23A and a drain electrode 23B. In other words, the source electrode 23A and the drain electrode 23B are provided not to overlap with the channel protective film 20 formed on the oxide semiconductor film 14 each other. A protective film 24 is formed so as to cover a part of the oxide semiconductor film 14, the channel protective film 20, the source electrode 23A, and the drain electrode 23B. The protective film 24 is provided for the purpose of protecting inside of the thin film transistor 4, and composed of the same material or the like as the protective film 16 of the above-described first embodiment.

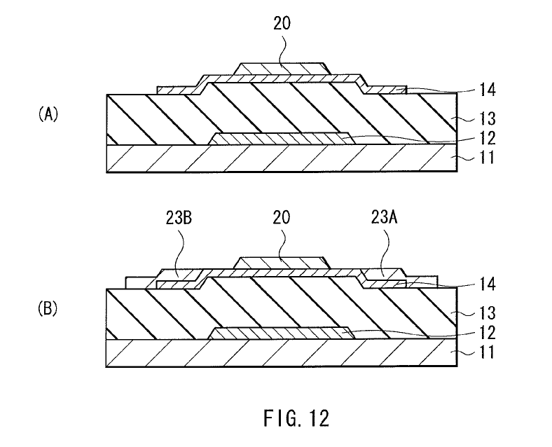

The thin film transistor 4 may be manufactured, for example, as will be described next. First, as illustrated in FIG. 12(A), like the thin film transistor 3 of the above-described third embodiment, the channel protective film 20 and the oxide semiconductor film 14 are sequentially patterned and formed by etching using the photoresist. Next, as illustrated in FIG. 12(B), on the oxide semiconductor film 14, the source electrode 23A and the drain electrode 23B are formed so as not to overlap the formed channel protective film 20. Finally, the protective film 24 is formed by atomic layer deposition method described above. In addition, like the above-described third embodiment, it is desirable to perform the ozone treatment or the like before forming the protective film 24 in this embodiment. As described above, the thin film transistor 4 illustrated in FIG. 11 is completed.

As described above, the source electrode 23A and the drain electrode 23B may be formed so as not to overlap with the channel protective film 20. Even in the case of such a structure, it may be possible to obtain the same effects as the above-described first embodiment and the above-described third embodiment. In addition, although a region (exposed region) which is not covered with both of the channel protective film 20, and the source electrode 23A or the drain electrode 23B exists, since the oxygen in this exposed region is detached in a reduced-pressure atmosphere when forming the protective film 24, the resistance becomes low in the exposed region. Therefore, it may be possible to reduce a parasitic capacity without reducing the current of the thin film transistor 4 by a parasitic resistance.

Here, the ozone treatment or the like before forming the protective film may be performed in the manufacturing process of the thin film transistor of the above-described first embodiment and the above-described second embodiment. Further, in the above-described second embodiment, although the case where the channel protective film 17 is formed of the aluminum oxide film has been described as an example, it is not limited to this, and the channel protective film 17 is formed of the silicon oxide film, and the annealing treatment may be performed in the oxygen atmosphere in the subsequent step, like the above-described third embodiment and the above-described modification. Further, in the above-described third embodiment and the above-described modification, although the case where the channel protective film 20 is composed of the silicon oxide film has been described as an example, the channel protective film 20 may be composed of the aluminum oxide film.

Hereinbefore, although the present invention has been described with the embodiments and the modification, the present invention is not limited to the above-described embodiments and the like, and various modifications are available. For example, in the above-described embodiments and the like, although the case where the aluminum oxide film is formed by atomic layer deposition method has been described as an example, it is not limited to this, and the aluminum oxide film may be formed by other film-forming methods, for example, sputtering method or the like. However, as described above, in the case where atomic layer deposition method is used, since the aluminum oxide film may be uniformly formed with the ideal composition ratio, the gas barrier characteristics may be easily maintained.

Further, in the above-described embodiments and the like, although the example of the bottom-gate structure has been described as the thin film transistor, it is not limited to this, and the top-gate structure may be applied.

The present application contains subject matter related to that disclosed in Japanese Priority Patent Application JP 2008-174469 filed in the Japan Patent Office on Jul. 3, 2008, the entire contents of which is hereby incorporated by reference.

1-15. (canceled)

16. A thin film transistor comprising:
a gate electrode;
an oxide semiconductor film in which a channel region is formed corresponding to the gate electrode;
a pair of electrodes of a source electrode and a drain electrode formed on the oxide semiconductor film; and
a protective film provided so as to face the channel region of the oxide semiconductor film,
wherein,
the protective film contains an aluminum oxide film having a film thickness of 50 nm or less.

17. The thin film transistor according to claim 16, wherein the protective film is composed of a stacked film of the aluminum oxide film and one or both of a silicon nitride film and a silicon oxide film.

18. The thin film transistor according to claim 16, wherein the protective film is formed so as to cover the channel region of the oxide semiconductor film and the pair of electrodes.

19. The thin film transistor according to claim 16, further comprising, as the protective film, (a) a first protective film formed so as to cover a top face of the oxide semiconductor film and (b) a second protective film formed so as to cover a top face of the first protective film, and a side face of the oxide semiconductor film,
wherein
each of the first protective film and the second protective film has an aperture,
the pair of electrodes is formed on the oxide semiconductor film through the apertures, and
one or both of the first protective film and the second protective film contain the aluminum oxide film.

20. The thin film transistor according to claim 16, further comprising, as the protective film, (a) a first protective film formed on the channel region of the oxide semiconductor film and (b) a second protective film formed so as to cover the first protective film and the pair of electrodes,
wherein
one or both of the first protective film and the second protective film contain the aluminum oxide film.

21. The thin film transistor according to claim 20, wherein the second protective film contains the aluminum oxide film.

22. The thin film transistor according to claim 20, wherein the pair of electrodes is formed on the oxide semiconductor film so as to cover end portions of the first protective film.

23. The thin film transistor according to claim 20, wherein the pair of electrodes is formed so as not to overlap with the first protective film on the oxide semiconductor film.

24. A method of manufacturing a thin film transistor comprising steps of:
forming a gate electrode on a substrate;
forming an oxide semiconductor film including a channel region corresponding to the gate electrode;
forming a pair of electrodes of a source electrode and a drain electrode on the oxide semiconductor film; and
forming a protective film so as to face the channel region of the oxide semiconductor film,
wherein,
the protective film is formed of a film that contains an aluminum oxide film having a film thickness of 50 nm or less.

25. The method of manufacturing a thin film transistor according to claim 24, wherein the film containing the aluminum oxide is formed by an atomic layer deposition method.

26. The method of manufacturing a thin film transistor according to claim 24, wherein an ozone treatment, an oxygen plasma treatment, or a nitrogen dioxide plasma treatment is performed on the oxide semiconductor film before the film containing the aluminum oxide is formed.

27. The method of manufacturing a thin film transistor according to claim 24, wherein the step of forming the protective film comprises steps of:
forming a first protective film including a silicon oxide film on the channel region of the oxide semiconductor film;
performing an annealing treatment on the oxide semiconductor film in an oxygen atmosphere after the first protective film is formed; and
forming a second protective film containing the aluminum oxide so as to cover the first protective film and the pair of electrodes.

28. A display device including a display element, and a thin film transistor for driving the display element, the thin film transistor comprising:
a gate electrode;
an oxide semiconductor film in which a channel region is formed corresponding to the gate electrode;
a pair of electrodes of a source electrode and a drain electrode formed on the oxide semiconductor film; and
a protective film provided so as to face the channel region of the oxide semiconductor film,
wherein
the protective film contains an aluminum oxide film having a film thickness of 50 nm or less.
